(19) United States
(12) Patent Application Publication
(10) Pub. No.: US 2008/0096136 A1
(43) Pub. Date: Apr. 24, 2008

(54) METHOD OF FORMING MASK PATTERN OF SEMICONDUCTOR DEVICE

(76) Inventors: Jong-Doo Kim, Seoul (KR); Se-Jin Park, Seoul (KR); Yong-Suk Lee, Seoul (KR); Kee-Ho Kim, Seoul (KR)

Correspondence Address: SHERR & NOURSE, PLLC, 620 HERNDON PARKWAY, SUITE 200, HERNDON, VA, 20170, US

(21) Appl. No.: 11/846,837

(22) Filed: Aug. 29, 2007

(30) Foreign Application Priority Data
Sep. 1, 2006 (KR) 10-2005-0084302

(51) Int. Cl. H01L 21/311; G03F 7/00

(52) U.S. Cl. 430/296; 430/313; 156/345.3

(57) ABSTRACT

A method of forming a photoresist pattern for etching an underlying layer of a semiconductor device. A surface of a semiconductor substrate is coated with photoresist. A mask bias is controlled for a mask writer apparatus depending on a mask target critical dimension. The photoresist is exposed and developed based on the controlled mask bias, thus forming a photoresist pattern. The underlying layer is etched along the photoresist pattern and the photoresist pattern is removed.

The present application claims priority under 35 U.S.C. 119 to Korean Patent Application No. 10-2005-0084302, filed on Sep. 1, 2006, which is hereby incorporated by reference in its entirety.

### BACKGROUND

The fabrication process of a semiconductor device may include deposition of several thin layers, such as a polysilicon layer, an oxide layer, a nitride layer, and a metal layer over a semiconductor wafer. These layers may be patterned through photolithographic processes including an etch process, an ion implantation process and other processes. Higher resolutions of the photolithographic processes used to form a micro pattern may increase the number of devices per unit area on the wafer.

Photolithographic processes include processes of forming photoresist patterns. Photolithographic processes also include processes which use photoresist patterns to create patterns in the conductors, semiconductors, and insulators on the wafer. For example, contact holes may be formed by etching an insulation layer using a photoresist pattern as an etch mask. The photoresist pattern may be formed coating a photoresist on the layer to be etched, exposing the photoresist by employing a prepared exposure mask, and selectively removing the photoresist using a chemical solution.

The critical dimension (CD) of a pattern that can be implemented with a photolithographic process varies with the wavelength of a light source used in the exposure process. The CD of a device pattern is determined by the minimum width of exposure in a photoresist pattern. A minimum width of exposure corresponds to the maximum resolution of photolithography process. Resolutions of the photolithography process are greatly influenced by a wavelength of the light source used, and a numerical aperture (NA) of exposure equipment. Factors related to the exposure mask may include factors involving the mask shape, including a binary intensity mask (BIM) and a phase shift mask (PSM). Deep UV (DUV) laser and an electron beam (E-beam) used in a mask writer apparatus (an exposure apparatus) may factor into the resolution of processes. For example, a pattern for a micro contact hole can be formed using a 50-KeV E-beam and PSM to improve resolutions.

If a mask is fabricated using a DUV laser, corner rounding may occur in the contact hole. Due to corner rounding, an accurate pattern may not be formed due to UV light diffraction. As shown in FIG. 1, even if the mask pattern is square, a contact hole pattern develops rounded corners, so that the pattern differs from the mask pattern. This will influence the total area of a contact hole in a mask pattern, and thus the electrical characteristics of the resulting contact. Corner rounding thereby effectively changes the CD of the process.

The area of the contact hole mask pattern can be regarded as an “effective mask CD” (hereinafter, referred to as “EMCD”). The EMCD can be expressed by the following equation. The EMCD can be used instead of the CD of a wafer.

$$S = \frac{{( MaskCD )}^{2} - 4 ( {r}^{2} - \frac{π {r}^{2}}{4} )}{2}$$

For example, if the EMCD (that is, the area of a contact hole mask pattern) of a DUV laser mask processing apparatus (i.e., a mask writer apparatus employing a DUV laser; for example, ALTA4300) and an E-beam mask processing apparatus (i.e., a mask writer apparatus employing an electron beam; for example, EBM3500) is calculated using conditions and data as shown in FIG. 2, a difference in the EMCD can bee seen as shown in FIG. 3. The area of the contact hole mask pattern varies with the mask writer apparatus due to a difference in a corner radius r, which results in a difference in the overall wafer process CD.

Thus, if a contact hole mask pattern is patterned with a DUV laser mask writer and an E-beam mask writer, the contact hole mask pattern area will be different due to the corner rounding phenomenon. This may cause differences between wafer critical dimensions, which may make it difficult to precisely form a desired pattern when a contact hole is formed in a subsequent process.

### SUMMARY

Embodiments relate to a method of forming a photoresist pattern of a semiconductor device which is suitable for etching an underlying layer. A desired pattern can be formed by changing a mask CD by controlling a mask bias.

A photoresist is coated over an entire surface of a semiconductor substrate in on which a layer is to be etched. A mask bias is controlled in every mask writer apparatus depending on a mask target CD. The photoresist is exposed and developed based on the controlled mask bias, thus forming a photoresist pattern. The underlying layer is etched using the photoresist pattern, and the photoresist pattern is removed.

### DRAWINGS

FIG. 1 is a view illustrating a corner rounding phenomenon generated when forming contact holes using a mask writer with a DUV laser.

FIG. 2 illustrates calculations of mask pattern areas for mask writers using a DUV laser and an E-beam.

FIG. 3 is a graph showing the mask CD difference between the mask writers using a DUV laser and an E-beam.

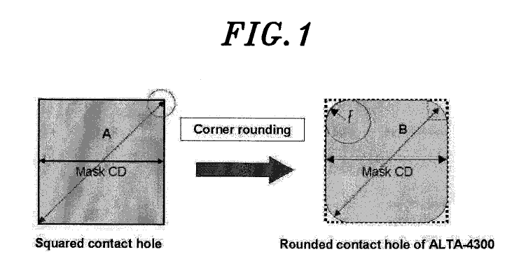

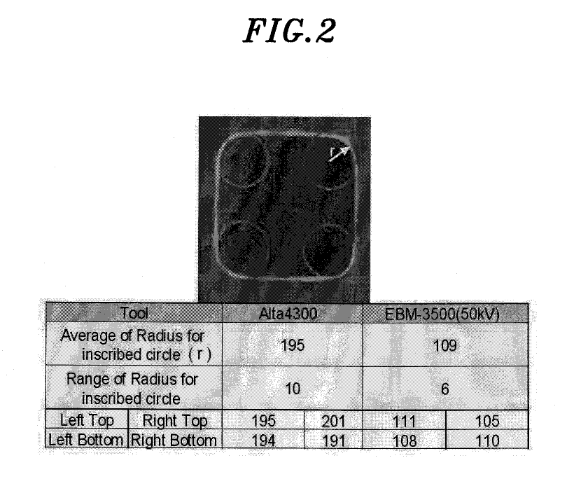

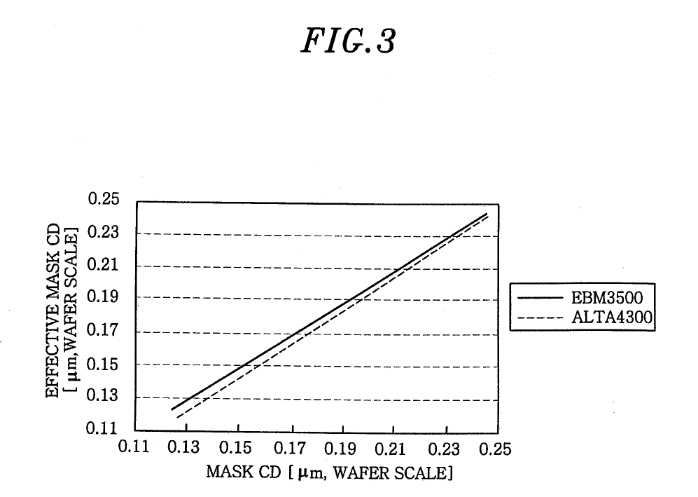

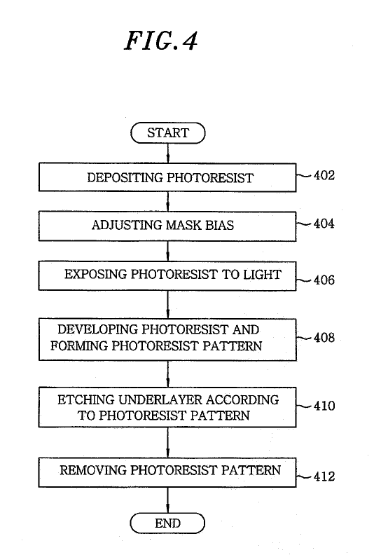

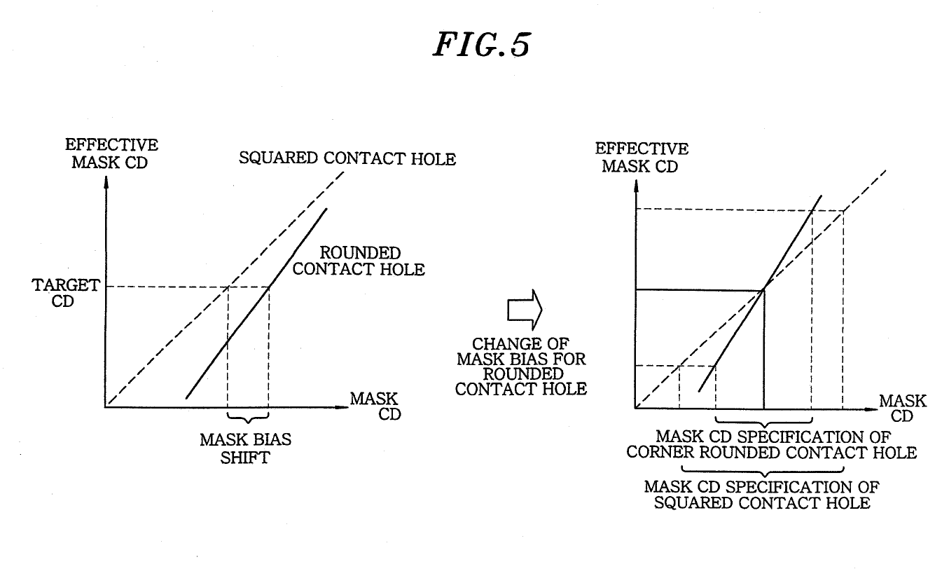

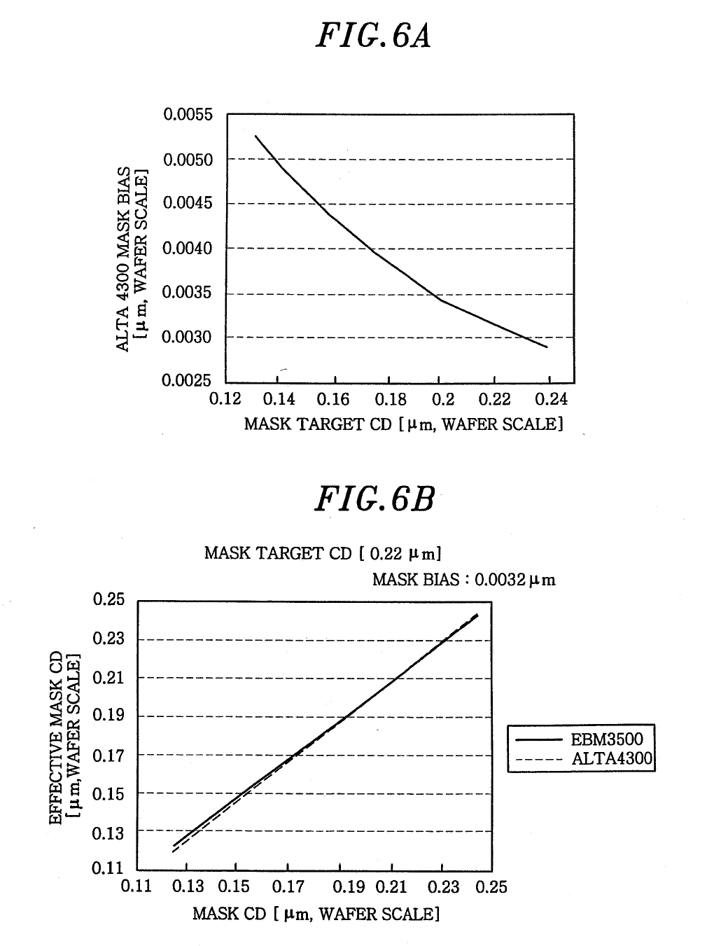

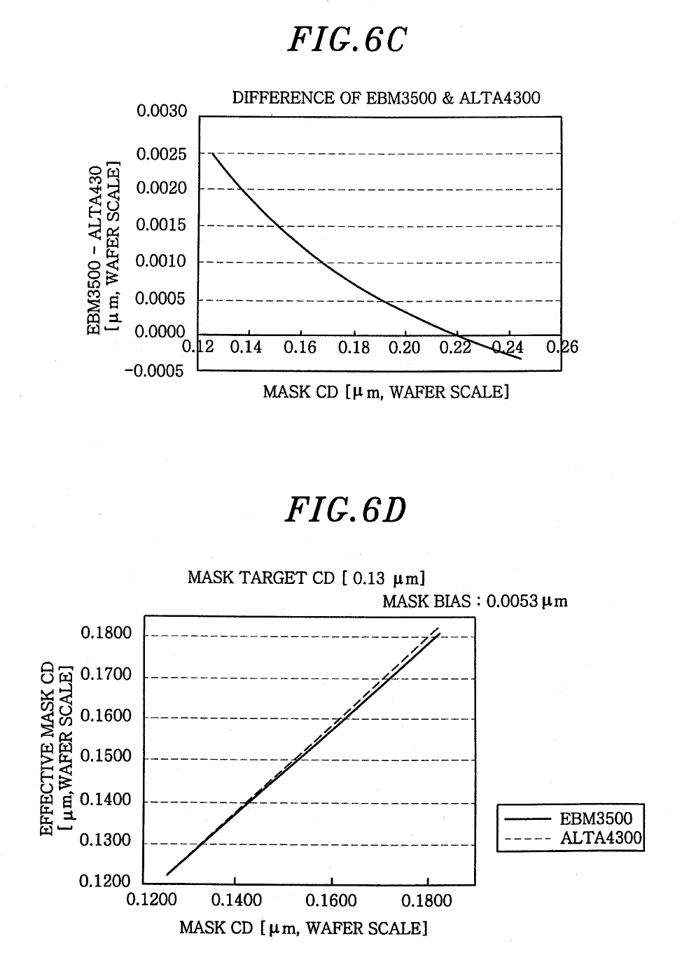

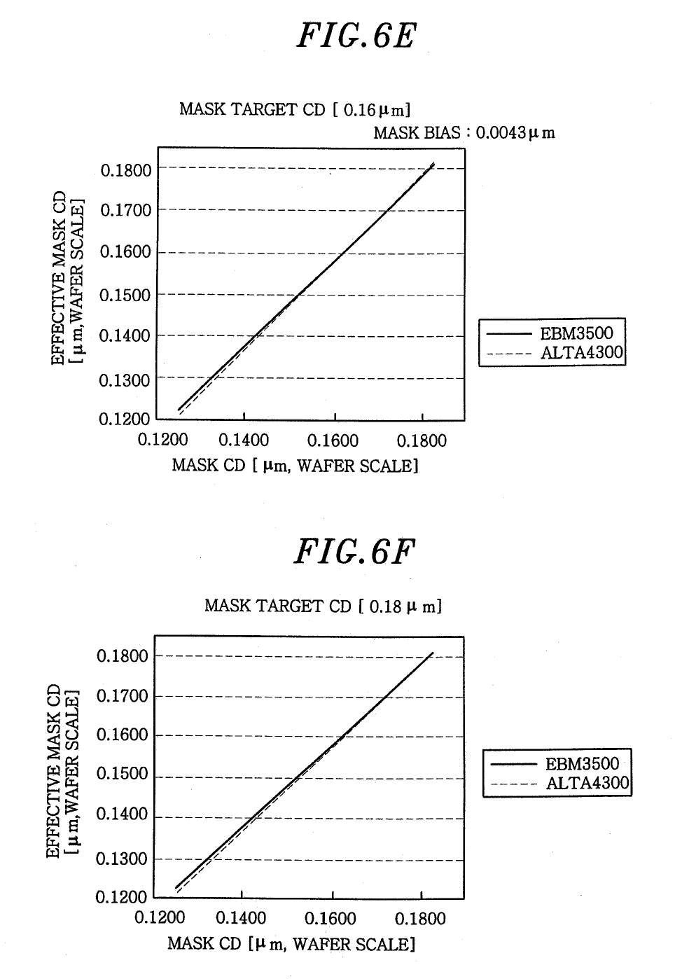

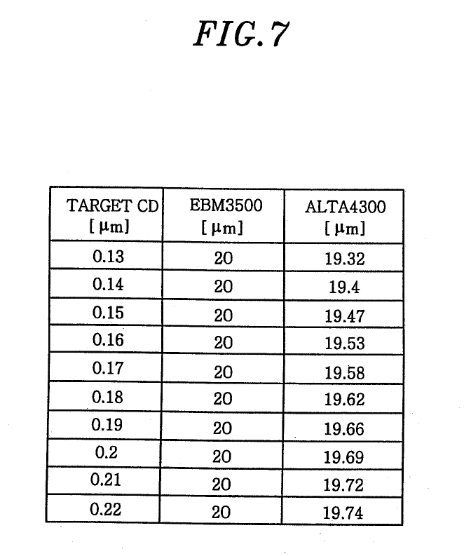

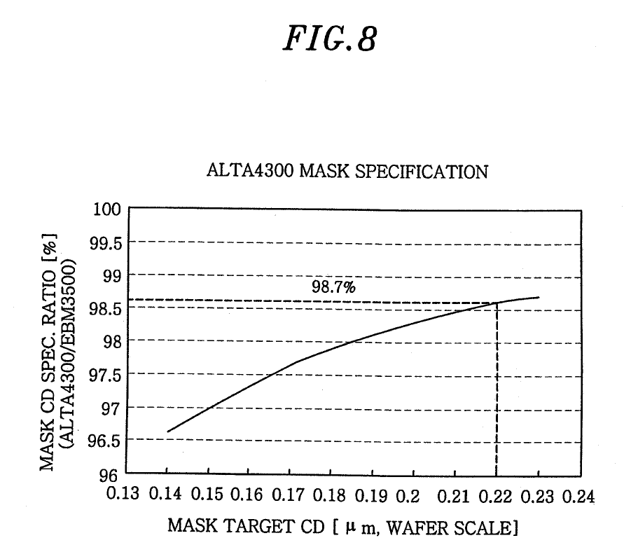

Example FIG. 4 is a flowchart illustrating a process of forming a desired mask pattern by controlling a mask bias in accordance with embodiments.

Example FIG. 5 is a view illustrating a mask bias controlled to form rounded contact holes in accordance with embodiments.

Example FIGS. 6A to 6F are views illustrating a mask bias controlled in response to a mask target CD, in accordance with embodiments.

Example FIG. 7 is a table illustrating mask CDs for mask writers depending on mask target CDs in accordance with embodiments.

Example FIG. 8 is a graph illustrating the ratio of the mask CD of the mask writer using a DUV laser and the mask CD of the mask writer apparatus using an E-beam in accordance with embodiments.

### DESCRIPTION

In embodiments, a photoresist may be coated over the entire surface of a semiconductor substrate in which an underlying layer is to be etched. A mask bias may be controlled for every mask writer depending on a mask target CD. In other words, the mask bias to be applied to the mask critical dimension may be computed based on the mask writer that is being used and the target critical dimension. The photoresist may be exposed and developed based on a controlled mask bias to form a photoresist pattern. The underlying layer may be etched using the photoresist pattern and the photoresist pattern may then be removed. The mask bias may be calculated by comparing an effective critical dimension of the DUV laser mask processing apparatus to that of an E-beam mask processing apparatus.

Example FIG. 4 is a flowchart illustrating a process of forming a desired mask pattern by controlling a mask bias in accordance with embodiments. It is hereinafter assumed that the photoresist pattern and the mask pattern have the same conceptual design.

Referring to example FIG. 4, a semiconductor substrate, in which a layer is to be etched, may be coated with photoresist, by a method such as spin coating, in step S402. The photoresist coating process may be preceded by a pre-treatment process including cleaning, dry, etc., and depositing an adhesion promotion coating using, for example, hexamethyl-disilazane (HMDS) or the like. After the photoresist is applied, a soft bake process for removing solvent or the like may be used.

Before the exposure process is performed, a mask bias may be controlled for each mask writer apparatus (exposure apparatus) according to a desired pattern in step S404. A process of controlling the mask bias is described later on in detail.

The photoresist may be exposed based on the controlled mask bias by using the mask writer (exposure apparatus) in step S406. The mask writer may include, for example, an apparatus employing a DUV laser, such as ALTA4300, or an apparatus employing an E-beam, such as EBM3500, and the like.

The exposed photoresist may be developed to form a photoresist pattern (a mask pattern) in step S408. When using, for example, a positive type photoresist, the photoresist pattern can be developed by removing a photoresist portion, hardening the photoresist with a hard bake process, and curing the photoresist using UV light. An underlying layer may be etched along the photoresist pattern, thus forming underlying layer patterns, such as contact holes and metal lines, in step S410. The photoresist pattern is removed in step S412. The photoresist pattern may be removed through an ashing process employing a gas, for example, O₂, N₂ or Ar.

The process of controlling the mask bias in step S404 is described below in detail. Example FIG. 5 is an illustration of a mask bias which may be controlled to form rounded contact holes in accordance with embodiments. To form a mask pattern according to a target CD, a mask bias may be shifted. In the case of corner-rounded contact holes and squared contact holes, the area of the EMCD of a desired pattern is induced.

Example FIG. 6A is a graph illustrating a mask bias with respect to a desired mask CD according to embodiments. When the mask target CD is 0.22 μm, the mask bias may be shifted and set to approximately 0.0032 μm. The mask CD of the mask writer using a DUV laser, such as ALTA4300, may be moved. The resulting mask bias is illustrated in example FIG. 6B.

Example FIG. 6C is a graph illustrating a difference in the mask CD according to the mask writer apparatus after the mask bias is controlled according to embodiments. From example FIG. 6C, it can be seen that after the mask bias is shifted and set to approximately 0.0032 μm, there is no difference in the mask CDs of the mask writers using a DUV laser (for example, ALTA4300) and an E-beam (for example, EBM3500).

Example FIG. 6D is a graph illustrating the results of the mask bias that was shifted and controlled when the mask target CD was set to 0.13 μm according to embodiments. Example FIG. 6E is a graph illustrating the results of the mask bias that was shifted and controlled when the mask target CD was set to 0.16 μm according to embodiments. Example FIG. 6F is a graph illustrating the results of the mask bias that was shifted and controlled when the mask target CD was set to 0.18 μm according to embodiments. From the above drawings, mask bias values, which are controlled to form a desired pattern according to a mask target CD, can be known.

Example FIG. 7 is a table illustrating mask CDs for mask writers depending on mask target CDs in accordance with embodiments. From example FIG. 7, mask CDs of the mask writers using an E-beam (for example, EBM3500) and a DUV laser (for example, ALTA4300) according to mask target CDs can be known.

Example FIG. 8 is a graph illustrating the ratio of the mask CDs of the mask writers using a DUV laser and an E-beam in accordance with embodiments. From example FIG. 8, it can be seen that a ratio according to a wafer size is approximately 98.7%. Thus, the same wafer process margin can be obtained by increasing the mask bias by about 3.2 nm or reducing the mask CD by about 1.3% in the event that a mask pattern is formed with the mask writer using a DUV laser (for example, ALTA4300) rather than the mask writer using an E-beam (for example, EBM3500).

Thus, in the manufacture of a semiconductor device, a photoresist may be coated and patterned. A mask bias may be shifted and controlled for each mask writer apparatus. The photoresist may be exposed and developed. An underlying layer may be etched along the mask pattern area, forming a desired photoresist pattern.

As described above, according to embodiments, a photoresist may be coated over the entire surface of a semiconductor substrate in which an underlying layer is formed. A mask bias may be controlled for every mask writer apparatus depending on a mask target CD. The photoresist may be exposed and developed based on a controlled mask bias to form a photoresist pattern. The underlying layer is etched along the formed photoresist pattern and the photoresist pattern is then removed. Accordingly, a photoresist pattern of a desired pattern may be formed by controlling a mask bias for every mask writer apparatus in the formation process of a semiconductor device.

A photoresist pattern of a desired pattern may be formed by controlling the mask bias of a mask writer using a DUV laser with respect to a mask writer using an E-beam. Accordingly, costs may be reduced.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
coating a surface of a semiconductor substrate with photoresist;
controlling, depending on a mask target critical dimension, a mask bias for a mask writer;
exposing and developing the photoresist based on the controlled mask bias, thus forming a photoresist pattern; and
etching an underlying layer using the photoresist pattern as a mask.

2. The method of claim 1, wherein the mask writer apparatus includes a mask writer apparatus employing a deep ultraviolet laser and a mask writer apparatus employing an electron beam.

3. The method of claim 1, wherein in the control of the mask bias, a mask bias of a mask writer apparatus employing a deep ultraviolet laser is controlled with respect to a mask writer apparatus employing an E-beam based on the mask target critical dimension.

4. The method of claim 1, wherein the photoresist pattern is removed after said etching.

5. A method comprising:
coating a surface of a semiconductor substrate with photoresist;
computing a mask bias to be applied to a mask critical dimension based on a mask writer that is being used and a target critical dimension; and
forming a photoresist pattern according to the mask critical dimension to which the mask bias is applied.

6. The method of claim 5, wherein the mask writer is a deep ultraviolet laser mask processing apparatus.

7. The method of claim 6, wherein the mask bias is calculated by comparing an effective critical dimension of the deep ultraviolet laser mask processing apparatus to an effective critical dimension of an electron beam mask processing apparatus.

8. The method of claim 5, wherein said forming a photoresist pattern comprises exposing and developing the photoresist based on the computed mask bias.

9. The method of claim 8, comprising etching an underlying layer on the semiconductor substrate using the photoresist pattern as a mask.

10. The method of claim 9, wherein the photoresist pattern is removed after said etching.

11. An apparatus configured to:
coat a surface of a semiconductor substrate with photoresist;
compute a mask bias to be applied to a mask critical dimension based on a mask writer that is being used and a target critical dimension; and
form a photoresist pattern according to the mask critical dimension to which the mask bias is applied.

12. The apparatus of claim 11, wherein the mask writer is a deep ultraviolet laser mask processing apparatus.

13. The apparatus of claim 12, wherein the mask bias is calculated by comparing an effective critical dimension of the deep ultraviolet laser mask processing apparatus to an effective critical dimension of an electron beam mask processing apparatus.

14. The apparatus of claim 11, wherein the photoresist pattern is formed by exposing and developing the photoresist based on the computed mask bias.

15. The apparatus of claim 14, configured to etch an underlying layer on the semiconductor substrate using the photoresist pattern as a mask.

16. The apparatus of claim 15, wherein the photoresist pattern is removed after said etching.
